(19) United States
(12) Patent Application Publication
(10) Pub. No.: US 2015/0146484 A1
(43) Pub. Date: May 28, 2015

(54) MEMORY SYSTEM INCLUDING MULTI-LEVEL MEMORY CELLS AND PROGRAMMING METHOD USING DIFFERENT PROGRAM START VOLTAGES

(71) Applicant: SAMSUNG ELECTRONICS CO., LTD., SUWON-SI (KR)

(72) Inventors: BONG-YONG LEE, SUWON-SI (KR); YU-SIK CHOI, SOKCHO-SI (KR)

(21) Appl. No.: 14/546,824

(22) Filed: Nov. 18, 2014

(30) Foreign Application Priority Data
Nov. 25, 2013 (KR) 10-2013-0143945

(51) Int. Cl. G11C 16/10

(52) U.S. Cl. CPC G11C 16/10
USPC 365/185.03

(57) ABSTRACT

A method of programming multi-level memory cells includes defining a first program start voltage and a second program start voltage higher than the first program start voltage, programming first memory cells among the MLC to the first program state using a program operation that begins programming of the first memory cells at the first program start voltage, and programming second memory cells among the MLC to the second program state using a program operation that begins programming of the second memory cells at the second program start voltage.

### CROSS-REFERENCE TO RELATED APPLICATIONS

This application claims the benefit of Korean Patent Application No. 10-2013-0143945, filed on Nov. 25, 2013, the subject matter of which is hereby incorporated by reference.

### BACKGROUND

The inventive concept relates generally to memory devices, memory systems and methods of programming the memory cells of a memory system.

Continuous demands for ever greater data storage capacity per unit area of a memory device (i.e., data integration density) has motivated the incorporation of memory cells capable of storing two or more bits of data per memory cell (i.e., multi-level memory cells, or MLC), in contemporary nonvolatile memory devices, such as flash memory. However, as the number of bits stored per memory cell increases, the plurality of threshold voltage distributions uniquely and respectively associated with each memory cell program state become more and more narrow, and the respective read margins between adjacent threshold voltage distributions shrink. These realities increase the possibility of read errors arising when the data programmed to MLC is subsequently read from memory.

New approaches are required to ensure the reliability of data stored in MLC, particularly MLC configured to store three or more bits of data.

### SUMMARY

According to an aspect of the inventive concept, there is provided a method of programming a memory system including multi-level memory cells (MLC) configured to be programmed in accordance with a first program state and a second program state, wherein the first program state is indicated by a first threshold voltage distribution (“distribution”) and the second program state is indicated by a second distribution having a higher level than the first distribution. The method comprises; defining a first program start voltage and a second program start voltage higher than the first program start voltage, programming first memory cells among the MLC to the first program state using a program operation that begins programming of the first memory cells at the first program start voltage, and programming second memory cells among the MLC to the second program state using a program operation that begins programming of the second memory cells at the second program start voltage.

According to another aspect of the inventive concept, there is provided a method of programming a memory system including multi-level memory cells (MLC) configured to be programmed in accordance with first through Nth program states, wherein each one of the first through Nth program states is respectively indicated by a successively higher threshold voltage distribution. The method comprises; defining first through Nth program start voltages respectively corresponding to the first through Nth program states, programming an Mth set of MLC to an Mth program state among the first through Nth program states by initially applying an Mth program start voltage, ‘N’ being a natural number greater than 2, and ‘M’ being a natural number less than or equal to N, wherein the Mth program start voltage is higher than a first program start voltage initially applied during the programming a first set of MLC to the first program state, and the Mth program start voltage is lower than an Nth program start voltage initially applied during the programming of an Nth set of MLC to the Nth program state.

According to another aspect of the inventive concept, there is provided a method of programming a memory system including multi-level memory cells (MLC) configured to be programmed in accordance with a selected one of first through Nth program states, wherein each one of the first through Nth program states is indicated by a respective, and successively higher threshold voltage distribution. The method comprises; defining respective first through Kth program start voltages;

grouping at least the first program state into a first group of program states, and grouping at least the Nth program state into a second group of program states to define K groups of program states, programming a first set of MLC to the first program state by initially applying a first program start voltage, programming a Jth set of MLC to a Jth program state, and thereafter programming a Jth+1 set of MLC to a Jth+1 program state by initially applying a Jth program start voltage higher than the first program start voltage, wherein the Jth program state and the Jth+1 program state are grouped in an Dth group of program states, wherein ‘N’, ‘K’, ‘J’ and ‘D’ are respective natural numbers, N being greater than 3, K being less than N, J being less than N and greater than 1, and D being less than K.

### BRIEF DESCRIPTION OF THE DRAWINGS

Certain embodiments of the inventive concept, or relevant aspects of certain embodiments of the inventive concept are illustrated in the accompanying drawings in which:

FIG. 1 is a block diagram illustrating a memory system according to an embodiment of the inventive concept;

FIG. 2 is a block diagram further illustrating in one example the memory device 200 of FIG. 1;

FIG. 3 is a conceptual diagram illustrating one possible configuration for the memory cell array 210 of FIG. 2;

FIG. 4 is a partial circuit diagram illustrating in one example a memory block included in the memory cell array 210 of FIG. 3;

FIG. 5 is a cross-sectional view illustrating in one example a memory cell that may be configured for use as a multi-level memory cell (MLC) within the memory block of FIG. 4;

FIG. 6 is a graph showing respective threshold voltage distributions that may be obtained by programming a memory device using an approach that applies the same program start voltage without regard to different program states;

FIG. 7 is a graph showing in one example a range of threshold voltage distributions that may be defined for the memory cell of FIG. 5;

FIG. 8 is a graph showing a shift level for the respective threshold voltage distributions assuming that the memory cell of FIG. 5 is a 3 bit MLC;

FIG. 9 further illustrates in an expanded view a modified threshold voltage distribution corresponding to the Nth program state of FIG. 7;

FIG. 10, inclusive of FIGS. 10A, 10B and 10C, graphically illustrates the development of threshold voltage distributions for a MLC being programmed using an approach wherein different program start voltages are used in view of different program states;

FIG. 11 further illustrates in an expanded view a final threshold voltage distribution for a memory device having been programmed using the approach of FIG. 10;

FIG. 12 is a graph showing a shift level for the respective program start voltages of FIG. 11;

FIG. 13, inclusive of FIGS. 13A, 13B and 13C, is a flowchart summarizing in one example a method of programming a memory system according to certain embodiments of the inventive concept;

FIG. 14 is a graph showing in one example certain respective threshold voltage distributions that may be obtained by programming a memory device using the approach described in relation to FIG. 13;

FIG. 15 is a timing diagram illustrating voltage levels that may be applied to a memory cell array during a program operation with respect to a first program state of FIG. 14;

FIG. 16 is a timing diagram illustrating voltage levels applied to a memory cell array during a program operation with respect to the second through Nth program states of FIG. 14;

FIG. 17 is a graph showing in another example certain respective threshold voltage distributions that may be obtained by programming a memory device using the approach described in relation to FIG. 13;

FIG. 18 is a block diagram illustrating a memory card system that may incorporate a memory system according to an embodiment of the inventive concept;

FIG. 19 is a block diagram illustrating a computing system that may incorporate a memory system according to an embodiment of the inventive concept; and

FIG. 20 is a block diagram illustrating a solid state disk (SSD) that may be implemented using a memory system according to an embodiment of the inventive concept.

### DETAILED DESCRIPTION

Hereinafter, the inventive concept will be described in some additional detail with reference to the accompanying drawings. The inventive concept may, however, be embodied in many different forms and should not be construed as being limited to only the illustrated embodiments. Rather, these embodiments are provided so that this disclosure will be thorough and complete, and will fully convey the scope of the inventive concept to those of ordinary skill in the art. Although a few embodiments of the inventive concept have been shown and described, it would be appreciated by those of ordinary skill in the art that changes may be made in these exemplary embodiments without departing from the principles and scope of the inventive concept as defined by the following claims and their equivalents. Throughout the drawings and written description, like reference numbers and labels denote like or similar elements.

The terminology used herein is for the purpose of describing particular embodiments only and is not intended to be limiting of the inventive concept. As used herein, the singular forms ‘a’, ‘an’, and ‘the’ are intended to include the plural forms as well, unless the context clearly indicates otherwise. It will be further understood that the terms ‘comprises’ and/or ‘comprising,’ when used in this specification, specify the presence of stated features, integers, steps, operations, elements, and/or components, but do not preclude the presence or addition of one or more other features, integers, steps, operations, elements, components, and/or groups thereof.

It will be understood that, although the terms ‘first’, ‘second’, ‘third’, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Unless otherwise defined, all terms (including technical and scientific terms) used herein have the same meaning as commonly understood by one of ordinary skill in the art to which the inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “and/or” includes any and all combinations of one or more of the associated listed items. Expressions such as “at least one of,” when preceding a list of elements, modify the entire list of elements and do not modify the individual elements of the list.

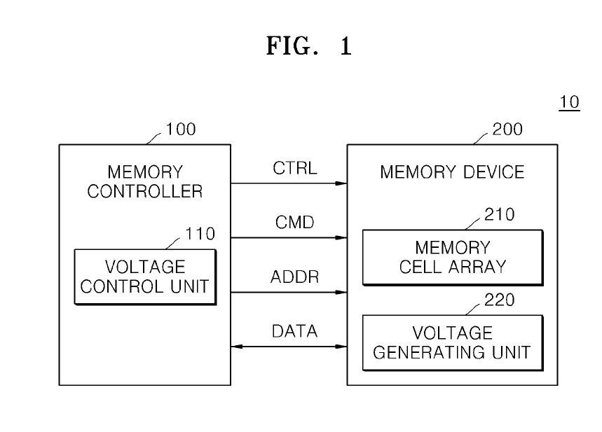

FIG. 1 is a block diagram illustrating a memory system 10 according to an embodiment of the inventive concept.

Referring to FIG. 1, the memory system 10 generally comprises a memory controller 100 and a memory device 200. The memory controller 100 comprises a voltage control unit 110. The memory device 200 comprises a memory cell array 210 and a voltage generating unit 220.

The memory controller 100 may be used to control the overall operation of the memory device 200. In this regard, the memory controller 100 may provide the memory device 200 with one or more address(es) ADDR, command(s) CMD, and/or control signal(s) CTRL to cause the execution of, at a minimum, program (or write), read, and erase operations by the memory device 200. Write data or read data, DATA, may be exchanged between the memory controller 100 and the memory controller 200 as the result of a program or read operation.

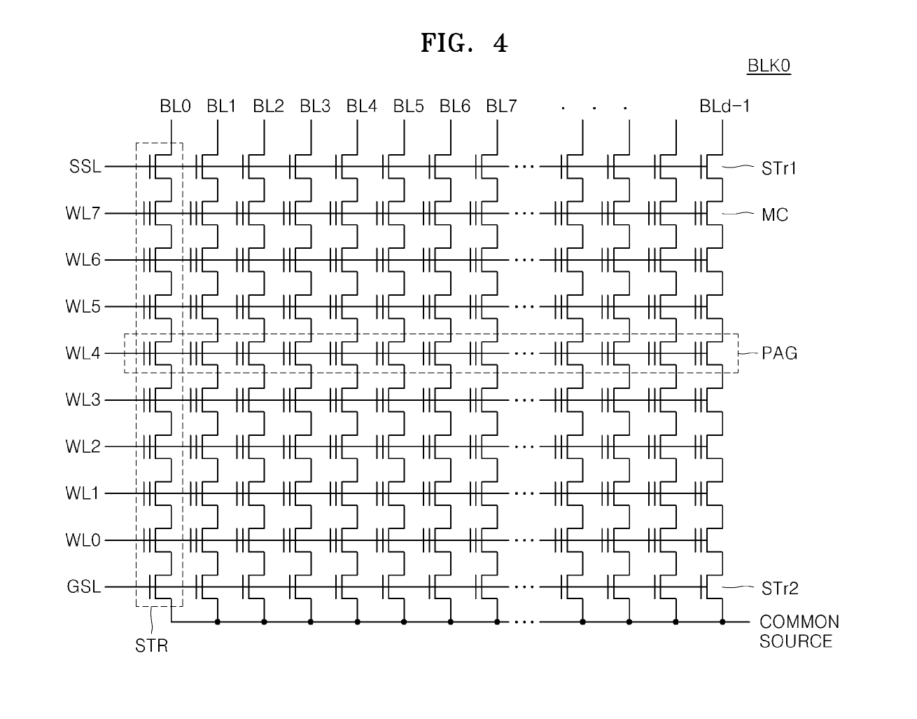

With reference to FIGS. 1 and 4, the memory cell array 210 arranges a large number of memory cells according to word lines WL0 through WL7 and bit lines BL0 through Bid−1. In certain embodiments of the inventive concept, the memory cells will be flash memory cells, such as NAND flash memory cells or NOR flash memory cells, configured to operate as multi-level flash memory cells (MLC) capable of storing at least two bits of data per MLC.

The embodiments of the inventive concept described hereafter assume the use of flash MLC, but those skilled in the art will recognize that other types of nonvolatile memory cells, such as resistive type memory cells (e.g., resistive random access memory (RAM)), phase change random access memory (PRAM), and/or magnetic random access memory (MRAM), might alternately or additionally be used. In certain embodiments of the inventive concept, the constituent memory cell array maybe configured as a three-dimensional memory cell array (e.g., a vertical NAND flash memory cell array).

As is conventionally understood, the MLC arranged in a particular block of flash MLC may be collectively erased by application of one or more erase voltage(s) during an erase operation. However, each MLC in a flash memory device may be individually (or group) programmed to a particular “program state”. Here, each program state corresponds to a unique data value that may be programmed to the MLC by applying an appropriate set of control voltages/currents to (e.g.,) the word line and/or bit line associated the MLC being programmed. Thus, assuming the use of a 3-bit MLC configured to store three bits of data, a total of eight (8) unique data values may each be respectively programmed to the MLC in accordance with an erase state (E) or one of seven possible program states (P1, P2, P3, P4, P5, P6 and P7, collectively referred to as “P1 through P7”). The data value of the MLC may thereafter be “read” by discriminating the threshold voltage exhibited by the MLC in view of a range of defined threshold voltage distributions (hereafter, “distributions”)

Thus, referring to FIG. 4, following a successfully completed program operation, one or more memory cells (MC) to which the program operation was directed should have a threshold voltage falling within either a distribution associated with the erase state E, or one of the distributions respectively associated with one of a first program state through a last (Nth) program state. In this context, ‘N’ will be a natural number greater than 2. Thus, for a 2-bit MLC, N will be 3; for a 3-bit MLC, N will be 7, etc.

Returning to FIG. 1, the voltage control unit 110 may be used to generate certain control signal(s) CTRL applied to the memory device 200. For example, the control signals provided by the voltage control unit 110 may control the provision of word line voltages and bit line voltages variously applied during program, read, or erase operations. During each program, read, erase operation, it is possible that the voltage control unit 110 will cause different word line voltage(s) to be applied to different word lines, and/or different bit line voltages to be applied to different bit lines within the memory cell array 210.

As will be appreciated by those skilled in the art, certain program operations executed by flash memory devices use an iterative approach to the programming of one or more memory cells. Each succession of program iterations (or program loops) will begin with a “program start voltage” (Vstart) that is initially applied to a selected word line. Hence, the voltage control unit 110 may be used to define first through Nth program start voltages (Vstart_1 through Vstart_N) respectively corresponding to first through Nth program states (P1 through PN) for a MLC.

In certain embodiments of the inventive concept, the voltage control unit 110 may determine the first through Nth program start voltages (Vstart_1 through Vstart_N), such that the Nth program start voltage (Vstart_N) has a highest voltage level among the first through Nth program start voltages, and the first program start voltage (Vstart_1) has a lowest voltage level among the first through Nth program start voltages. It follows that the second program start voltage through n−1 th program start voltage (Vstart_2 through Vstart_N−1) will successively increase in voltage level between the first program start voltage (Vstart_1) and the Nth program start voltage (Vstart_N).

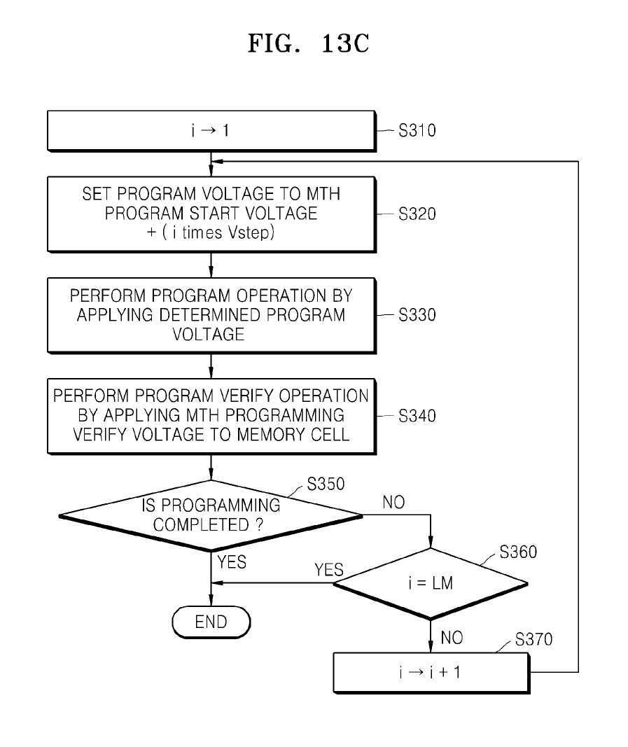

With this capability and operational understanding associated with the voltage control unit 110, memory systems according to embodiments of the inventive concept are capable of adaptively setting the program start voltage for a program operation directed to a memory cell depending on the program state to which the memory cell will be programmed. Exemplary approaches to accomplishing this novel programming method will be described in some additional detail in relation to FIGS. 13, 14, 15, 16 and 17 hereafter.

According to different embodiments of the inventive concept, each program state defined for a MLC in a memory cell array may have a different program start voltage, or alternately, two or more program states defined for the MLC may have a same program start voltage.

The voltage control unit 110 of FIG. 1 may also be configured to define the particular level of an inhibit voltage selectively applied to the bit line of certain MLC being programmed to the second through Nth program states (P2 through PN), for example. That is, during a program operation associated with each one of the second through Nth program states (P2 through PN), the voltage control unit 110 will need to maintain certain MLC in a group of MLC being programmed in an “inhibit state” during one or more inhibit interval. Thus, in the context of the foregoing, the “Nth inhibit interval” of a program operation corresponds to the Nth program state during which the program operation is executed using a program voltage that is less than the Nth program start voltage (Vstart_N).

In this regard, the voltage control unit 110 may set a logic level of an inhibit voltage during an inhibit interval to ‘high,’ and the logic level of the inhibit voltage to ‘low’ after the inhibit interval elapses. Thus, the voltage control unit 110 may generate a first inhibit voltage having a logically high level and apply the first inhibit voltage to bit line(s) connected to selected memory cell(s) during the inhibit interval, while also generating a second inhibit voltage having a logically low level and apply the second inhibit voltage to bit line(s) connected to the selected memory cells following the inhibit interval. Accordingly, when a program operation directed to one of the relatively lower program states is executed, the possibility of a program disturbance occurring with respect to memory cells to be programmed to one of the relatively higher program states during the inhibit interval may be markedly reduced.

Thus, according to the certain embodiments of the inventive concept, the second through Nth program start voltages (Vstart_2 through Vstart_N) may be successively higher in voltage than the first program start voltage (Vstart_1). Accordingly, when a program operation with respect to a first program state P1 is performed and the corresponding program voltage has a lower voltage level than the second program start voltage (Vstart_2), a corresponding program voltage is not applied to the memory cells MC that are to be programmed to the second program state P2.

Conventionally, a program disturbance may arise in relation to the memory cells to be programmed to the second program state P2 due to the program operation with respect to the first program state P1. However, according to the embodiments of the inventive concept, the voltage control unit 110 may generate an appropriate control signal such that a predetermined voltage is applied to a bit line during an inhibit interval so as to prevent program disturbance in the memory cells MC to be programmed to the second program state P2.

In FIG. 1, the voltage generating unit 220 may be used to actually generate the control voltages defined by the control signals provided by the voltage control unit 110 (e.g., word lines voltages, bit line voltages, program voltages, program verify voltages, read voltages, erase voltages, etc.). Thus, consistent with the foregoing, the voltage generating unit 220 may be used to generate any one (e.g., an Mth program start voltage, or Vstart_M) among the first through Nth program start voltages (Vstart_1 through Vstart_N.

The voltage generating unit 220 may also be used to gradually increase the level of a program voltage over an incrementing count of program loops. That is, the voltage generating unit 220 may in certain embodiments be used to generate a pulse-type program start voltage having a first level during a first program loop, and then to generate a pulse-type program voltage having a second higher level (e.g., increased by a defined step voltage “Vstep”) during a second program loop, etc. As will be recognized by those skilled in the art, this programming approach is sometimes referred to as an incremental stepping pulse programming (ISPP) method.

When programming one or more memory cell(s) using an iterative program operation, each successively-executed program loop comprises a program step that is usually followed by a program verification step. Program loops continue until the memory cell(s) are properly programmed, or until a maximum program loop count is reached. Accordingly, in certain embodiments of the inventive concept, each program step is performed using a pulse-type program voltage, and each program verification step is performed using a pulse-type program verify voltage. As a program loop count value increases, the respective program voltage and program verify voltage may increase according to variously defined step increases.

In alternate embodiments of the inventive concept, the voltage control unit 110 may also be included in the memory device 200 rather than the memory controller 100.

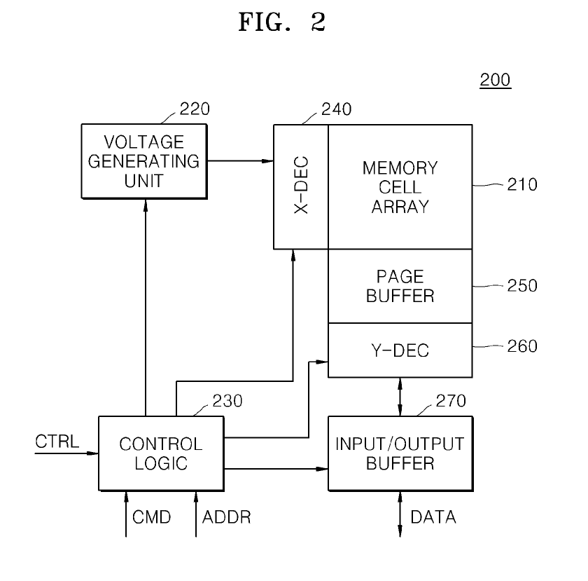

FIG. 2 is a block diagram further illustrating in one example the memory device 200 of the memory system 10 of FIG. 1.

Referring to FIG. 2, the memory device 200 comprises the memory cell array 210 and voltage generating unit 220 in addition to control logic 230, a row decoder 240, a page buffer 250, a column decoder 260, and an input/output (I/O) buffer 270.

The control logic 230 may be used to provide various control signals necessary to the programming of data to, the erasing of data stored in, and the reading of data from the memory cell array 210 in response to command(s) CMD, address(es) ADDR, and control signal(s) CTRL received from the memory controller 100.

Various control signals provided by the control logic 230 may be used to control the operation (and the inter-operation) of voltage generating unit 220, row decoder 240, column decoder 260, and I/O buffer 270. For example, the control logic 230 may be used to provide a voltage control to the voltage generating unit 220, a row address to the row decoder 240, and a column address to the column decoder 260.

Under the control of the control logic 230, the voltage generating unit 220 may be used to selectively generate and apply word line voltages to the word lines. For example, the voltage generating unit 220 may be used to generate and apply to a selected word line any one of the first through Nth program start voltages (Vstart_1 through Vstart_N) respectively corresponding to the first through Nth program states (P1 through PN). The voltage generating unit 220 may also be used to generate the incrementally increasing program voltages and program verify voltages.

The row decoder 240 is operationally connected to the memory cell array 210 via word lines and may be used to selectively activate one or more word lines in response to the row address received from the control logic 230. For example, during a read operation, the row decoder 240 may apply a read voltage to a selected word line and a pass voltage to unselected word lines. During a program operation, the row decoder 240 may apply a program voltage to a selected word line and a pass voltage to unselected word lines.

The page buffer 250 is operationally connected to the memory cell array 210 via bit lines. Thus, during a read operation, the page buffer 250 may be configured to operate as a sense amplifier and provide “read data” retrieved from the memory cell array 210 to an external circuit. Alternately, during a program operation, the page buffer 250 may be configured to operate as a write driver and program “write data” to selected memory cells of the memory cell array 210.

In response to the column address received from the control logic 230, the column decoder 260 may select read data stored in the page buffer 250 and transfer the read data to the I/O buffer 270 during a read operation. Alternately, the column decoder 260 may select write data stored in the I/O buffer 270 and transfer the write data to the page buffer 250. The I/O buffer 270 may also be used to store write data received from the memory controller 100, or to transfer read data retrieved from the memory cell array 210 to the memory controller 100.

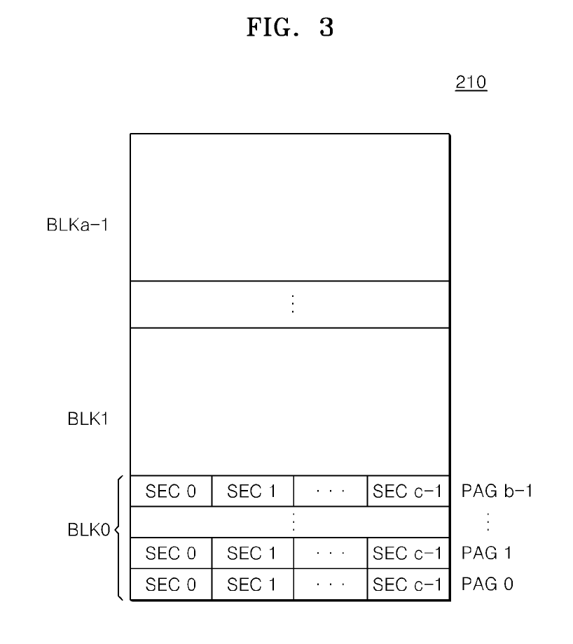

FIG. 3 is a conceptual diagram illustrating one possible configuration for the memory cell array 210 of FIG. 2.

Referring to FIG. 3, the memory cell array 210 is assumed to be a flash memory cell array. The memory cell array 210 is logically and/or physically divided into memory blocks BLK0 through BLKa−1. Each memory block BLK0 through BLKa−1 is further divided into pages PAG0 through PAGb−1, and each page is still further divided into sectors SEC0 through SECc−1, ‘a’, ‘b’, and ‘c’ being natural numbers. For convenience of illustration, the pages PAG0 through PAGb−1 and the sectors SEC0 through SECc−1 are illustrated only with respect to the memory block BLK0 in FIG. 3, but other memory blocks BLK1 through BLKa−1 may also have the same structure as the memory block BLK0.

FIG. 4 is a partial circuit diagram illustrating in one possible example the memory block BLK0 of memory cell array 210 of FIG. 3.

Referring to FIG. 4, the memory cell array 210 is assumed to be a NAND flash memory cell array, where the blocks BLK0 through BLKa−1 of FIG. 3 are implemented as illustrated in part. Referring to FIG. 4, the flash memory cells of block BLK0 are arranged according to respective strings STR including eight (8) serially connected memory cells MC arranged along bit lines BL0 through BLd−1. Each string STR also includes a drain select transistor Str1 and a source select transistor Str2 that are respectively connected at the two ends of each of the serially connected set of memory cells MC.

In a NAND flash memory having a structure like the one illustrated in FIG. 4, an erase operation is performed in block units, while program and read operations are performed in page units, each page being associated with one of the word lines WL0 through WL7. Thus, FIG. 4 shows by way of example eight (8) pages respectively associated with one of eight word lines WL0 through WL7 in the illustrated block BLK0. However, the blocks BLK0 through BLKa−1 of the memory cell array 210 may include any reasonable number of memory cells in arranged the strings, different pages configurations, etc.

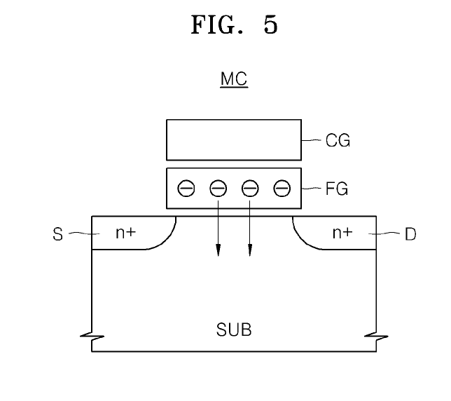

FIG. 5 is a cross-sectional view illustrating a memory cell MC that may be used in the flash memory cell array of FIG. 4.

Referring to FIG. 5, a source S and a drain D may be formed on a substrate SUB, and a channel area may be formed between the source S and the drain D. A floating gate FG is formed above the channel area, and an insulating layer such as a tunneling insulating layer may be disposed between the channel area and the floating gate FG. A control gate CG is formed above the floating gate FG, and an insulating layer such as a blocking insulating layer may be disposed between the floating gate FG and the control gate CG. The control voltages needed to program data to, erase data from, or read data from the memory cell MC may be variously applied to the substrate SUB, source S, drain D, and/or control gate CG.

Again assuming the use of flash MLC in the memory cell array 210 of FIGS. 2, 3, and 4, the data state—corresponding to a particular data value—stored by the memory cell MC may be read by discriminating the threshold voltage of the memory cell MC in view of a set of defined threshold voltage distributions. That is, the threshold voltage of the memory cell MC may be determined according to a quantity of electrical charge accumulated on the floating gate FG, wherein the greater the accumulated charge on the floating gate FG, the higher the threshold voltage of the memory cell MC.

However, some electrical charge stored in the floating gate FG of the memory cell MC may leak away into the substrate (arrow direction) due to various factor. As a result, the initially programmed threshold voltage of the memory cell MC may change over time. For example, some of the electrical charge stored in the floating gate FG may leak due to abrasion of the memory cell MC. That is, the insulating layer in a channel region of the substrate disposed between the Source S and Drain D and below the floating gate FG may become worn due to repeated access operations (e.g., program, erase, and read operations). Alternatively or additionally, electrical charge stored in the floating gate FG may leak due to a high-temperature stress, or a temperature difference between program and read times.

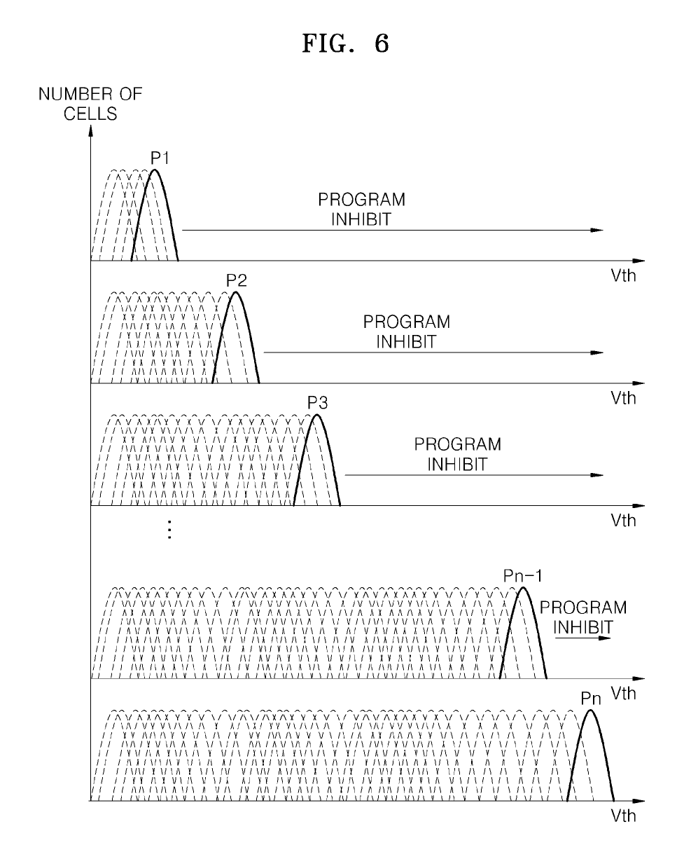

FIG. 6 is a graph illustrating a comparative example where respective program states (P1 through PN) are obtained for respective memory cells using a programming approach that uses the same program start voltage with respect to the programming of the different program states.

Referring to FIG. 6, the horizontal axis denotes a memory cell threshold voltage (Vth) and the vertical axis denotes a number of memory cells. As may be seen from FIG. 6, each respective program state (P1 through PN) is obtained by beginning with the same program start voltage (Vstart) (i.e., a program voltage applied during a first program loop and having the same level regardless of the particular program state being programmed). In FIG. 6, a successively higher threshold voltages (dotted line representation) for the memory cell(s) being programmed are obtained for each successively performed program loop. Hence, as the program loop count value increases, the program operation(s) directed to remaining (non-inhibited) memory cells are performed with increasing an program voltage level. Once memory cell(s) reach their intended program state, however, programming is complete and they are thereafter maintained in a program inhibit state in order to prevent over-programming with respect to their intended program state.

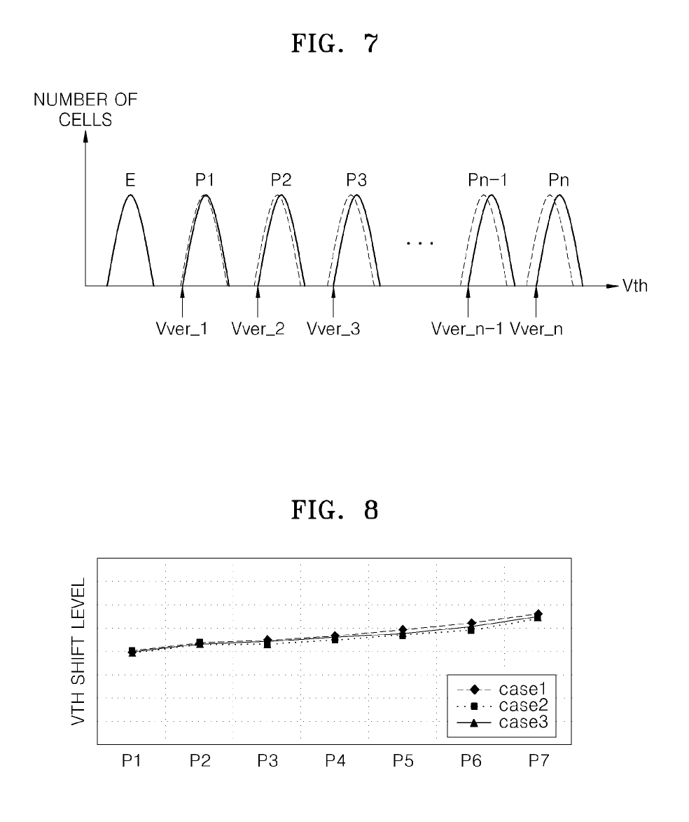

FIG. 7 is a graph illustrating an exemplary set of defined distributions to which the memory device of FIG. 5 may be programmed, assuming that the memory cell is configured to operate as a MLC having P1 through PN program states.

Referring to FIG. 7, the horizontal axis again denotes memory cell threshold voltage (Vth) and the vertical axis denotes a number of memory cells. Consistent with the illustrated comparative example of FIG. 6, the program operation is performed on memory cells using the same program start voltage with respect to the different program states. Hence, group memory cells having an intended threshold voltage defined by the program operation are shown by the solid line, where another group of memory cells having changed threshold voltages (i.e., changed outside the intended distribution following programming) are shown by the dotted line.

That is, when a memory cell is programmed to one of the first through Nth program states (P1 through PN), a program verify operation is performed to determine whether the programming of the memory cell is complete. In this regard, a voltage generating unit, like voltage generating unit 220 of FIG. 1, may receive a particular control signal indicating the need for a program verify operation, and in response may be used to generate and selectively apply one of first through Nth program verify voltages (Vver_1 through Vver_N).

Here, in certain embodiments of the inventive concept, the first program verify voltage (Vver_1) may correspond to a minimum threshold voltage for memory cell(s) programmed to the first program state P1, the second program verify voltage (Vver_2) may correspond to a minimum threshold voltage for memory cell(s) programmed to the second program state P2, and so on.

If memory cell(s) being verified in relation to a program verify voltage are determined to be turned OFF (e.g., a current does not flow through the memory cell), then the memory cell(s) are determined to be successfully programming with respect to a given program state. In contrast, if memory cell(s) being verified in relation to a program verify voltage are determined to be turner ON (e.g., a current flows through the memory cell), then the memory cell(s) are determined to not yet be successfully programmed with respect to the given program state.

With reference back to FIG. 6, once memory cell(s) are determined to be successfully programmed to an intended program state as the result of a program verify operation and are program inhibited, they may nonetheless be disturbed or over-programmed to undesired threshold voltage states, as denoted by a dotted line in FIG. 7 due to an external stimulus, material layer abrasion, etc. When such erroneously programmed memory cells are subsequently read in relation to read voltage(s) (Vread) defined in view of the program verify voltages, read errors may be generated with respect to memory cells having aberrant threshold voltages less than or equal to a corresponding program verify voltage.

FIG. 8 is a graph showing a shift level for a threshold voltage according to the respective program states shown in FIG. 7.

Referring to FIG. 8, the horizontal axis denotes first through seventh program states (P1 through P7), and the vertical axis denotes a shift level for a corresponding threshold voltage (Vth). A threshold voltage “shift level” denotes a difference between each program verify voltage and a minimum threshold voltage associated with a program state potentially having an undesirably modified distribution with respect to programmed memory cells. These relationships assume that the program operation uses the same program start voltage with respect to the different program states as illustrated in FIG. 6.

In each of the cases 1, 2 and 3 shown in FIG. 8, the threshold voltage level shift increases from the first program state P1 to the seventh program state P7. In other words, a threshold voltage level shift for programmed memory cells tends to increase in relation to the higher program states.

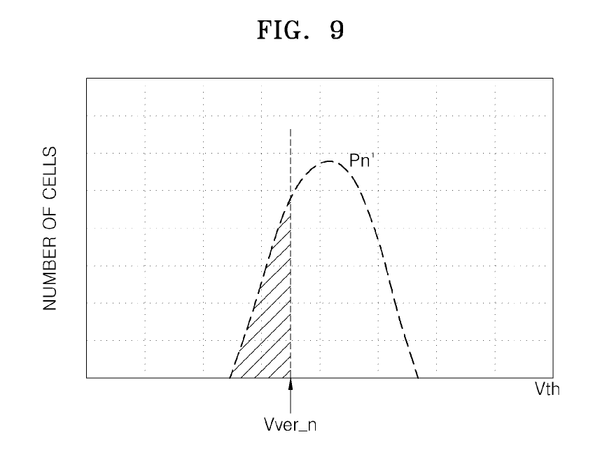

FIG. 9 further illustrates in an expanded view a modified threshold voltage distribution corresponding to the Nth program state of FIG. 7;

Referring to FIG. 9, memory cells programmed to an Nth program state may have an undesirable modified distribution PN′, denoted by a dotted line, due to some external stimulus, material layer abrasion, etc. Read errors may arise in relation to memory cells having threshold voltages less than or equal to the Nth program verify voltage (Vver_n) as shown by the shaded portion of the modified distribution.

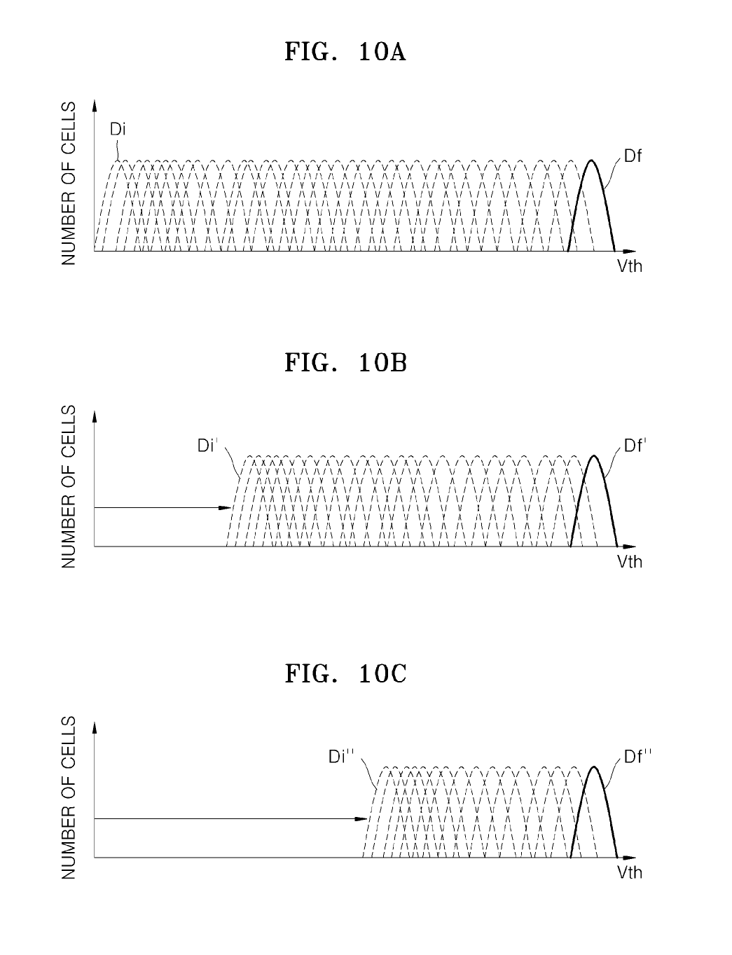

FIG. 10, inclusive of FIGS. 10A, 10B and 10C graphically showing the development of a desired distribution (Df) for memory cells programmed using a method capable of adaptively defining the level of a program start voltage.

Referring to FIG. 10A, a program voltage associated with a first program loop will be referred to as program start voltage (Vstart). A resulting initial distribution for memory cells being programmed by the illustrated program operation beginning with program start voltage is denoted as distribution Di. As a program loop count value increases, the program voltage also increases, and accordingly, the distribution of memory cells approaches a final (target) distribution Df.

Referring now to FIG. 10B, a different approach is illustrated by defining the program start voltage to be (Vstart+α) in relation to the approach of FIG. 10A. That is, a second program start voltage (Vstart+α) has a higher level than a first program start voltage (Vstart) of FIG. 10A by some predetermined amount. After performing an initial program loop using the second program start voltage (Vstart+α), a second initial distribution Di′ having a level higher than a first initial distribution Di in FIG. 10A is obtained. Here, the second initial distribution Di′ is significantly closer to closer to a final distribution Df′ than the first initial distribution Di.

Referring to FIG. 10C, this approach is further refined in relation to the final (target) distribution Df. That is, the first program loop begins at a third program start voltage (Vstart+β) developing a third initial distribution Di″ even closer to the final distribution Df″.

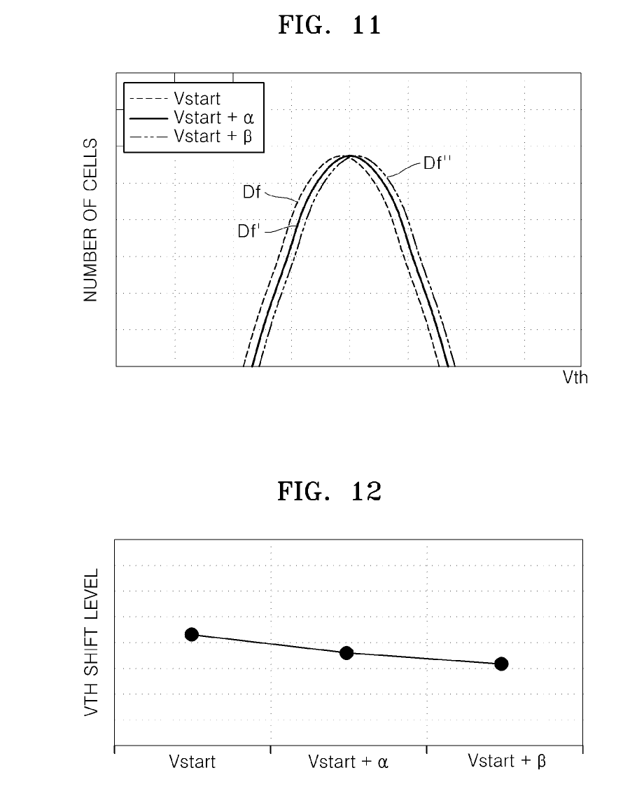

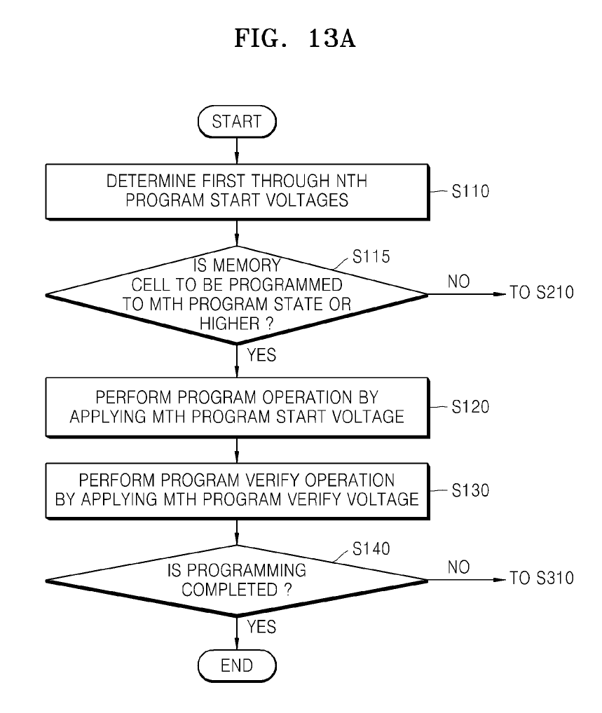

FIG. 11 further illustrates in an expanded view the final distribution Df for memory cells programmed using the approach of FIG. 10;

Referring to FIG. 11, a final distribution Df′ obtained by a program operation beginning with the second program start voltage (Vstart+α) is left shifted (i.e., increased in voltage level) relative to the final distribution Df obtained by the program operation beginning with the first program start voltage (Vstart). Further, the final distribution Df″ obtained by the program operation beginning with the third program start voltage (Vstart+β) is still more left shifted (i.e., further increased in voltage level) relative to the final distribution Df′ obtained by the program operation beginning with the second program start voltage (Vstart+α). As may be clearly understood at this point, programming methods according to embodiments of the inventive concept dramatically reduce the possibility of read errors arising.

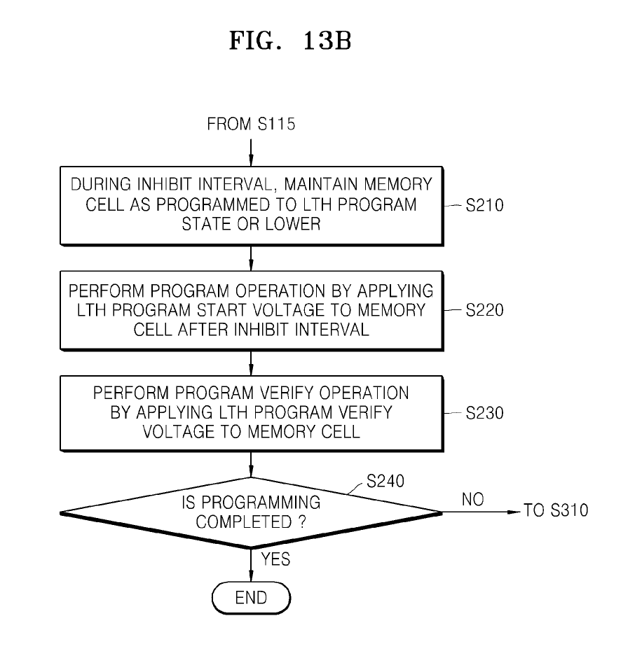

FIG. 12 graphically illustrates threshold voltage level shifts with respect to memory cells programmed according to the respective final distributions Df, Df′, and DF″ of FIG. 11.

Referring to FIG. 12, a shift level for threshold voltages of memory cells programmed using the third program start voltage (Vstart+β) is lower than a shift level for threshold voltages of memory cells programmed using the second or first program start voltage (Vstart, or Vstart+α). Also, a shift level for threshold voltages of memory cells programmed using the first program start voltage (Vstart+α) is lower than a shift level for threshold voltages of memory cells programmed using the first program start voltage (Vstart).

As noted above, the higher a program start voltage, the lower a threshold voltage shift level will be for programmed memory cells. Accordingly, in order to reduce the relative shift level for memory cell threshold voltages, a relatively high program start voltage should be set wherever possible.

FIG. 13, inclusive of FIGS. 13A, 13B and 13C, is a flowchart summarizing in one example a method of programming a memory cell in a memory system according to certain embodiments of the inventive concept;

Referring to FIG. 13A, first through Nth program start voltages (Vstart_1 through Vstart_N) are respectively determined in accordance with first through Nth program states (P1 through PN) (S110). Next, a determination is made as to whether or not a target memory cell is to be programmed to an Mth program state or higher (S115). (Thus, the illustrated example of FIG. 13 is drawn to the programming of an Mth program state among a set of first through Nth possible program states). If the target memory cell is not to be programmed to the Mth or higher program states (S115=No: that is, the target memory cell is programming complete in relation to an Lth or lower program state), then the method proceeds to step (S210) of FIG. 13B. However, if the target memory cell is to be programmed to the Mth program state or higher (S115=Yes), then a program operation is performed with respect to the Mth program state by applying an Mth program start voltage to at least one selected word line (S120). Here, ‘M’, ‘N’, and ‘L’ are all successive natural number, M being less than N and greater than L.

Then, an Mth program verify operation is performed by applying an Mth program verify voltage to the target memory cell (S130). Then, a determination is made as to whether the programming of the target memory cell is complete (S140).

In each of the foregoing method steps, the constituent elements of the embodiments shown in FIGS. 1, 2, 3, 4 and 5 may be used as described above. That is, the voltage generating unit 220 of FIG. 1 may be used to generate the appropriate control voltages under the control of the voltage control unit 1100.

Referring to FIG. 13B, the method of programming a memory cell continues following a determination (S115=No) that the target memory cell is programmed to an Lth program state or lower. Hence, during an inhibit interval of the ongoing program operation, a program inhibit state is maintained for the target memory cell (S210). That is, assuming that the target memory cell has been previously programmed to an Lth program state or lower among the first through Nth program states, the voltage control unit 110 may be used to maintain the target memory cell in a program inhibit state during the inhibit interval. After the inhibit interval, an inhibit voltage may be set such that the target memory cell may again be programmed. For example, a control signal may be generated such that a logically high (e.g., a power signal) inhibit voltage is applied to a bit line connected to the target memory cell during the inhibit interval.

Next, after the inhibit interval, the program operation continues by applying an Lth program start voltage to the target memory cell. That is, the voltage control unit 110 may be used to set an inhibit voltage such that target memory cell may be programmed following the inhibit interval. For example, the voltage control unit 110 may be used to generate a logically low (e.g., a ground signal) inhibit voltage applied to a bit line connected to the target memory cell following inhibit interval (S220).

The voltage generating unit 220 may be used to generate an Lth program start voltage corresponding to the Lth program state in response to the control signal, and may apply the Lth program start voltage to a selected word line connected to the target memory cell

Then, a program verify operation may be performed by applying an Lth program verify voltage to the target memory cell (S230). That is, the voltage generating unit 220 may be used to generate an Lth program verify voltage to determine whether the programming of the target memory cell to the Lth program state is complete by applying an Lth verify voltage to a selected word line connected to a memory cell.

Then, a determination is made as to whether the programming is complete (S250).

If the programming in determined to not be complete (S240=No), the method proceeds to step S310 of FIG. 13C.

In the determination of S240, if the memory cell being verified by the Lth program verify voltage is turned OFF, it may be determined that programming is complete and method ended. However, if the memory cell being verified by the Lth program verify voltage is turned ON, it may be determined that programming is not complete.

Referring to FIG. 13C, the method of programming the memory cell in a memory system consistent with embodiments of the inventive concept is essentially capable of executing an iteratively applied program loop.

An initial program loop “i” is assumed (S310).

For this program loop, the voltage control unit 110 sets a program voltage to be equal to the Mth program start voltage plus “i” times a predetermined voltage step (Vstep) (S320). This approach assumes the use of a ISPP programming method, wherein a program voltage is gradually increased according to the step voltage Vstep during each succeeding program loop.

Next, a program operation is performed for the current program loop by applying the program voltage to the target memory cell (S330). Here, the voltage generating unit 210 may be used to generate the program voltage of S320 in response to a control signal and apply program voltage to a word line connected to the target memory cell.

Then, a program verify operation is performed by applying the Mth program verify voltage to the target memory cell (S340). That is, the voltage generating unit 220 may be used again to generate the Mth program verify voltage in order to determine whether or not the programming of the target memory cell to the Mth program state is complete.

In view of the program verify operation (S340), a determination is made as to whether or not the programming of the target memory cell to the Mth program state is complete. If S350=Yes, the method ends. However, if S350=No, then the method potentially loops back to S320 through S360 and S370. That is, if the memory cell being verified in relation to the Mth program state is turned OFF, then it is determined that programming is complete. However, if the memory cell is turned ON, then it is determined that programming is not complete, and S360 is performed.

Assuming that the current loop count value “i” has not reached a maximum loop count value (LM) (S360=No), then the loop count is incremented (S370) and the method returns to S320.

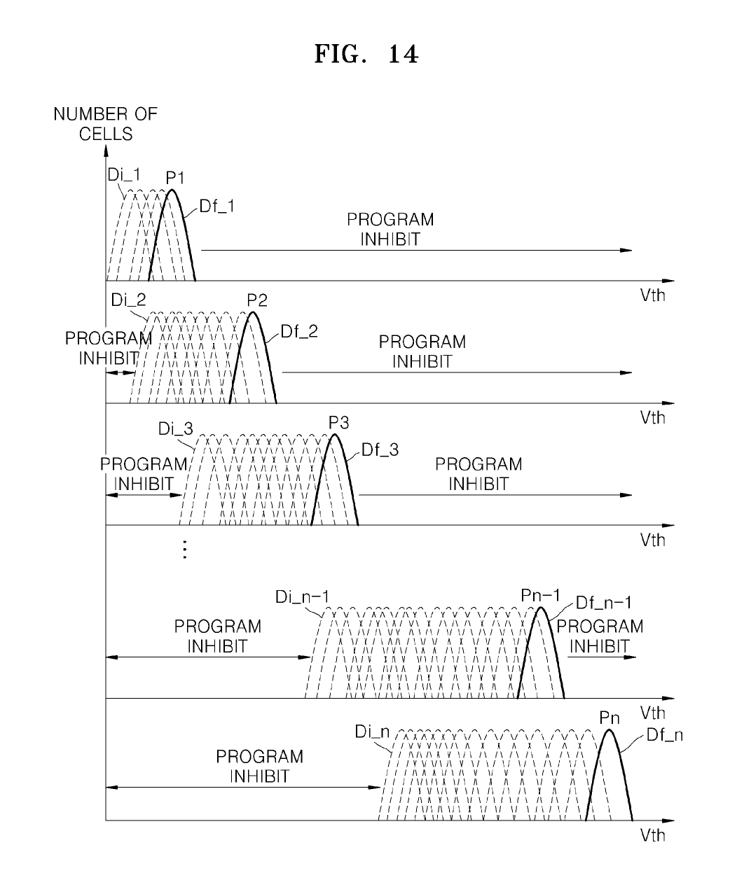

FIG. 14 is a graph showing in one example certain respective threshold voltage distributions that may be obtained by programming a memory cells using the approach described in relation to FIG. 13;

Referring to FIGS. 1 and 14, the voltage control unit 110 may be used to set first through Nth program start voltages (Vstart_1 through Vstart_N) differently according to first through Nth program states (P1 through PN). The voltage control unit 110 may also be used to determine the first through Nth program start voltages (Vstart_1 through Vstart_N) such that respective voltage levels successively increase from the first program start voltage (Vstart_1) to the Nth program start voltage (Vstart_N), wherein the first program start voltage (Vstart_1) has a lowest level among the first through Nth program start voltages (Vstart_1 through Vstart_N).

Accordingly, the first program start voltage (Vstart_1) is to (Vstart), the second program start voltage (Vstart_2) is set to (Vstart+α1), the third program start voltage (Vstart_3) is set to (Vstart+a2), and so forth until, the (N−1)th program start voltage (Vstart_N−1) is set to (Vstart+α(n−1)), and the Nth program start voltage (Vstart_N) is set to Vstart+αn, where a predetermined voltage level difference increases from α1 to αn, successively.

As described with reference to FIGS. 10 and 11, program start voltages having a relatively higher levels are used in to program memory cell to threshold voltages falling within respectively higher threshold voltage distributions. Also, as described with reference to FIG. 12, higher program start voltages tend to reduce the threshold voltage shift level for memory cells. Accordingly, when programming to a first program state P1 is performed by applying a first program start voltage (Vstart_1) having a lowest voltage level to “first memory cells” (i.e., memory cells intended to be programmed to the first program state), a first initial distribution Di_1 for the first memory cells is obtained.

When programming second memory cells to a second program state P2 using a second program start voltage (Vstart_2) higher than the first program start voltage (Vstart_1), a second initial distribution Di_2 of the second memory cells higher than the first initial distribution Di_1 is obtained, and so forth until when programming of an Nth program state PN is performed by applying the Nth program start voltage (Vstart_N) higher than all other program start voltages to Nth memory cells, an Nth initial distribution Di_n for the Nth memory cells highest of all initial distributions is obtained.

Once programming of the first memory cells is complete and final distribution Df_1 is obtained, the first memory cells will thereafter be maintained in a program inhibit state in order to prevent over-programming, and so on with respect to the other second through Nth memory cells.

In this regard according to the certain embodiments of the inventive concept, when performing a program operation with respect to the second through Nth program states (P2 through PN), the voltage control unit 110 may be used to maintain the second through Nth memory cells in a program inhibit state during an inhibit interval, and thereafter allow a program operation to be performed with respect to the second through Nth memory cells following the inhibit interval. The term “inhibit interval in a program operation” with respect to the Nth program state PN refers to an interval in which a program operation is performed using a program voltage lower than the Nth program start voltage (Vstart_N) when performing a program operation with respect to lower program states.

Thus, when programming second memory cells to a second program state P2, the second memory cells will be maintained in a program inhibit state during the inhibit interval in which a program operation with respect to a first program state P1 is performed using a program voltage that is lower than a second program start voltage Vstart_2 with respect to the first memory cells that are adjacent to the second memory cells. And when programming Nth memory cells to an Nth program state PN, the Nth memory cells may be maintained in a program inhibit state during an inhibit interval in which a program operation with respect to lower program states is performed with respect to (N−1)th memory cells by using a program voltage that is lower than the Nth program start voltage Vstart_N.

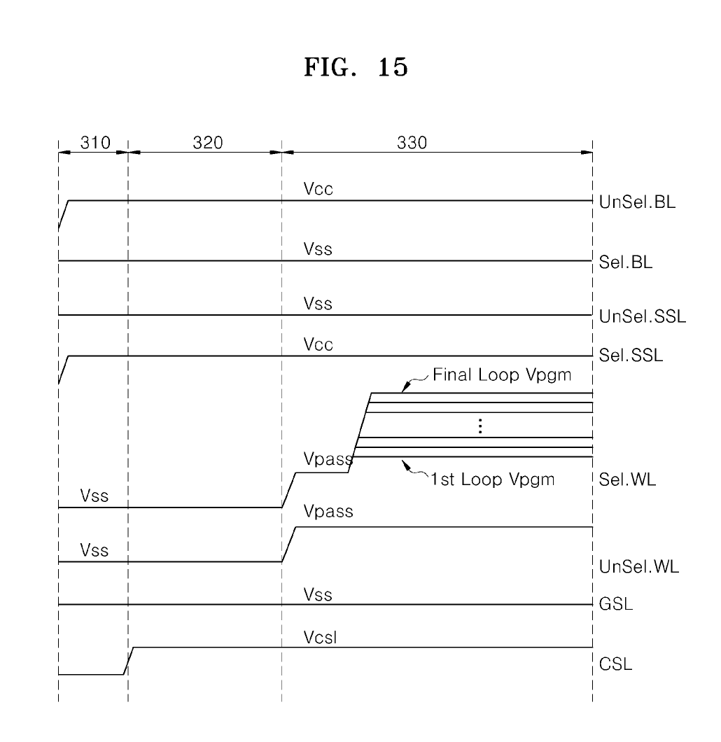

FIG. 15 is a timing diagram illustrating voltage levels applied to a memory cell array during a program operation with respect to the first program state P1 shown in FIG. 14.

Referring to FIG. 15, during a bit line setup interval 310, the voltage level of a selection bit line connected to a selection memory cell to be programmed may be a ground voltage (e.g., Vss), and a power voltage (e.g., Vcc) is applied to an unselected bit line that is not connected to the selection memory cell. Also, the power voltage may be applied to a selection string selection line (Sel.SSL) connected to a selection memory cell, and an unselected selection line SSL that is not connected to a selection memory cell is maintained at ground voltage. Also, a ground selection line GSL and a common source line CSL are also maintained at ground voltage.

Then, during a program preparation interval 320, a source voltage (Vcsl) is applied to the common source line CSL.

Then, during a programming interval 330, a pass voltage Vpass is applied to a selected word line (Sel.WL) and unselected word line (UnSel.WL) for channel boosting. Then, a program voltage is applied to the selected word line (Sel. WL, and a program voltage is gradually increased as a program loop count value increases.

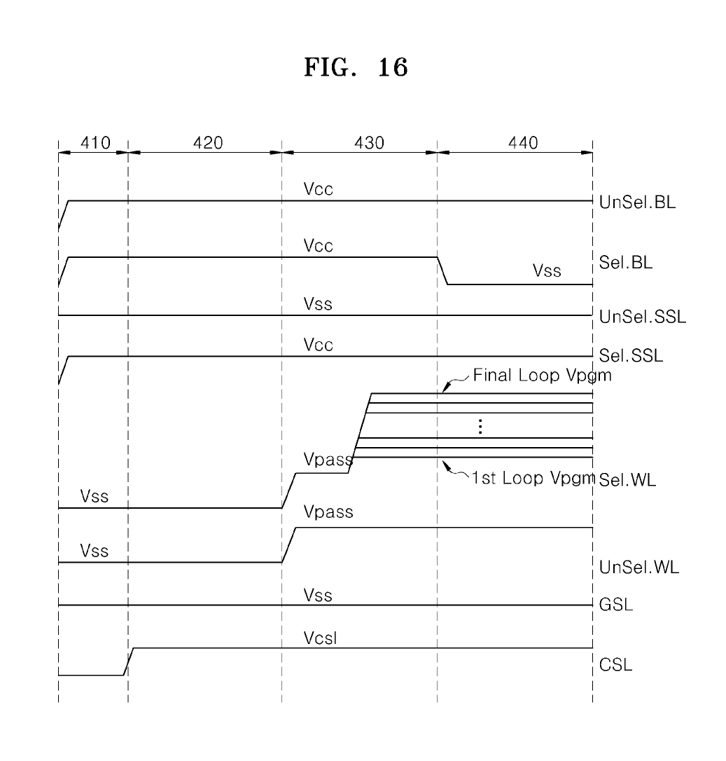

FIG. 16 is a timing diagram illustrating voltage levels applied to a memory cell when a program operation with respect to second through Nth program states P2 through PN as shown in FIG. 14.

Referring to FIG. 16, during the bit line setup interval 410, the power voltage is applied to a selected bit line (Sel.BL) connected to the memory cell to be programmed, and to unselected bit lines (UnSel.BL) not connected to the selected memory cell. Also, the power voltage is applied to the selection string selection line (Sel.SSL) connected to the selection memory cell, and unselected selection lines (SSL) not connected to the selection memory cell are maintained at ground voltage. Also, a ground selection line GSL and a common source line CSL are maintained at ground voltage.

During a program preparation interval 420, the source voltage Vcsl is applied to the common source line CSL.

During the program inhibit interval 430, in which a program operation with respect to a memory cell adjacent to the selection memory cell is performed at a program voltage lower than a program start voltage according to a program state to be programmed. Here, a pass voltage Vpass for channel boosting is commonly applied to a selected word line (Sel.WL) and unselected word lines (UnSel.Wl). Then, a program voltage is applied to the selection word line (Sel.WL), and a program voltage increases by stages as a program loop count value increases.

As described above, even when a pass voltage Vpass and a program voltage (Vpgm) are applied to a selected word line (Sel.WL), as a power voltage is applied to the selection bit line (Sel.BL), a program disturbance may not occur with respect to the selected memory cell.

During a programming interval 440 with respect to a memory cell adjacent to the selection memory cell is performed by using a program voltage that is equal to or higher than a program start voltage according to a program state to be programmed. Here, ground voltage is applied to the selected bit line (Sel.Bl), and accordingly, a program operation with respect to the second through Nth program states P2 through PN may be performed.

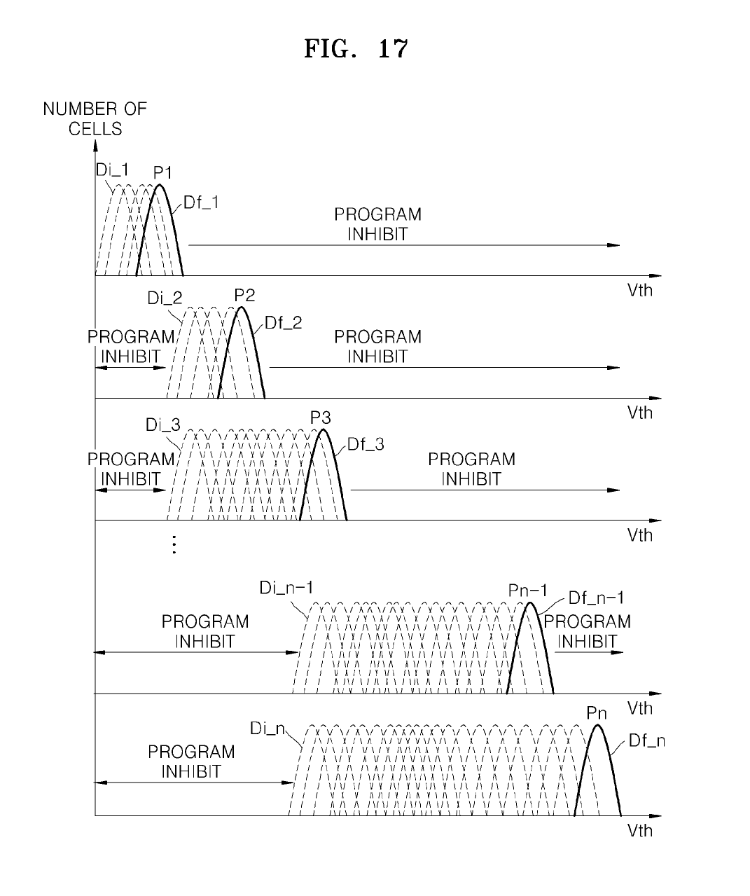

FIG. 17, much like FIG. 10, graphically shows the development of a desired distribution for memory cells programmed using a method capable of adaptively defining the level of a program start voltage, and adaptively applying a program inhibit state to various groups of memory cells. This outcome may be achieved by modifying the method of FIG. 13.

Referring to FIGS. 1 and 17, the voltage control unit 110 may be used to determine each of first through N/2th program start voltages (Vstart_1 through Vstart_N/2), for example, such that groups of two (2) first through Nth program states (P1 through PN) have the same program start voltage.

Here, the voltage control unit 110 may be used to group two or more program states (e.g., P2 & P3; PN−1 & PN) such that each program state in a particular group of program states uses the same program start voltage. All groups of program states in this regard may have an equal number of grouped program states or a different number.

Similar to the approach described with reference to FIGS. 10 and 11, a relatively higher program start voltage may be assigned to each successively higher group of program states with similar effect as those described in relation to FIG. 12.

Of further note with respect to the embodiment shown in FIG. 17, certain memory cells associated with corresponding groups of program states may be program inhibited for some period of time preceding application of the appropriate program start voltage. Thus, second memory cells and third memory cells respectively corresponding to the second program state P2 and the third program state P3, may be program inhibited for a period of time preceding application of a second program start voltage beginning the programming of both the second memory cells and the third memory cells.

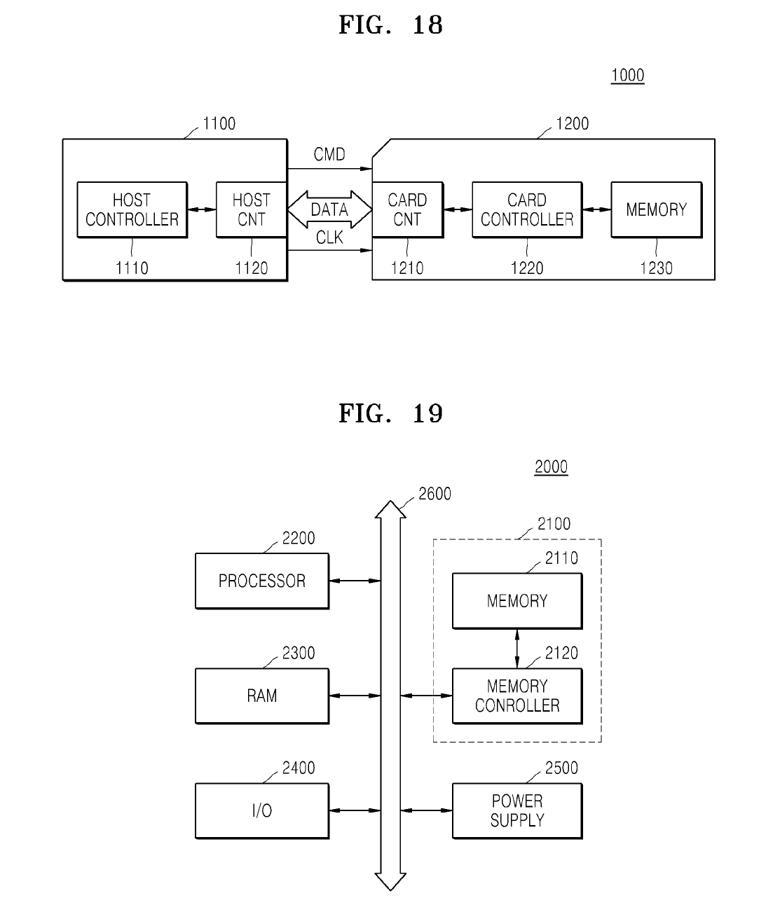

FIG. 18 is a block diagram illustrating a memory card system 1000 that may incorporate a memory system according to an embodiment of the inventive concept.

Referring to FIG. 18, the memory card system 1000 may include a host 1100 and a memory card 1200. The host 1100 may include a host controller 1110 and a host contact 1120. The memory card 1200 may include a card contact 1210, a card controller 1220, and a memory device 1230.

The host 1100 may write data to the memory card 1200 or read data stored in the memory card 1200. The host controller 1110 may transmit a clock signal CLK generated in a clock generator (not shown) in the host 1100 and data to the memory card 1200 through the host contact 1120.

In response to the command CMD received by using the card contact 1210, the card controller 1220 may store data in the memory device 1230 in synchronization with a clock signal generated by a clock generator (not shown) in the card controller 1220. The memory device 1230 may store data transmitted from the host 1100.

The memory card 1230 may be a compact flash card (CFC), a Microdrive, a smart media card (SMC), a multimedia card (MMC), a security digital card (SDC), a memory stick, or a universal serial bus (USB) flash memory driver.

FIG. 19 is a block diagram illustrating a computing system 2000 that may incorporate a memory system according to an embodiment of the inventive concept.

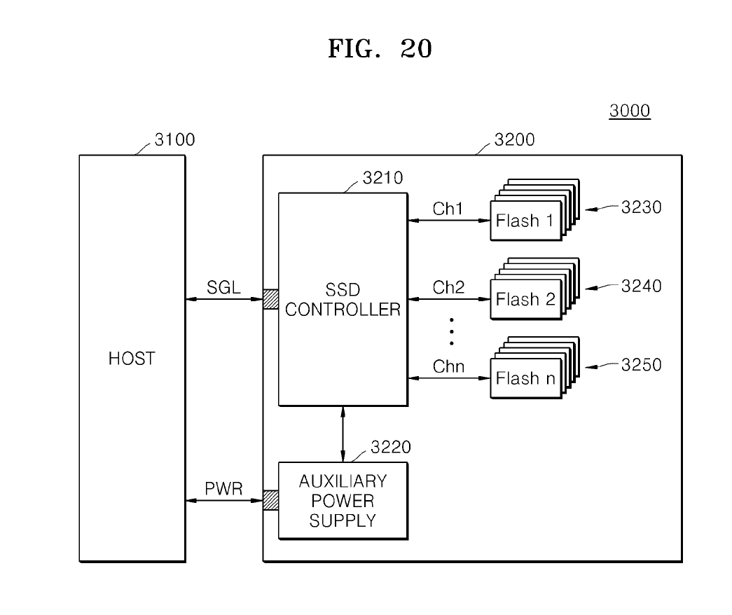

Referring to FIG. 19, the computing system 2000 may include a memory system 2100, a processor 2200, a RAM 2300, an input/output device 2400, and a power device 2500. Meanwhile, although not illustrated in FIG. 20, the computing system 2000 may further include ports via which to communicate with a video card, a sound card, a memory card, or a USB device, or other electronic appliances. The computing system 2000 may be a personal computer or a portable electronic device such as a laptop computer, a mobile phone, a personal digital assistant (PDA) or a camera.

The processor 2200 may perform particular computations or tasks. According to an embodiment of the inventive concept, the processor 2200 may be a micro-processor or a central processing unit (CPU). The processor 2200 may perform communication with the RAM 2300, the input/output device 2400, and the memory system 2100 via a bus 2600 such as an address bus, a control bus, or a data bus. According to an embodiment of the inventive concept, the processor 2200 may also be connected to an extension bus such as a peripheral component interconnect (PCI) bus.

The RAM 2300 may store data needed in operating the computing system 2000. For example, the RAM 2300 may be a DRAM, a mobile DRAM, an SRAM, a PRAM, an FRAM, an RRAM, and/or an MRAM.

The input/output device 2400 may include an input unit such as a keyboard, a keypad, or a mouse and an output unit such as a printer or a display. The power device 2500 may supply an operating voltage needed in operating the computing system 2000.

FIG. 20 is a block diagram illustrating a solid state disk (SSD) system 3000 that may incorporate a memory system according to an embodiment of the inventive concept.

Referring to FIG. 20, the SSD system 3000 may include a host 3100 and an SSD 3200. The SSD 3200 may transmit or receive a signal to and from the host 3100 via a signal connector, and may receive power via a power connector. The SSD 3200 may include an auxiliary power device 3220 and a plurality of memory devices 3230, 3240, and 3250. The SSD controller 3210 or the plurality of memory devices 3230, 3240, and 3250 may include a unit for detecting a dummy word line according to the embodiment of the inventive concept described above.

While the inventive concept has been particularly shown and described with reference to exemplary embodiments thereof, it will be understood that various changes in form and details may be made therein without departing from the scope of the following claims.

What is claimed is:

1. A method of programming a memory system including multi-level memory cells (MLC) configured to be programmed in accordance with a first program state and a second program state, wherein the first program state is indicated by a first threshold voltage distribution and the second program state is indicated by a second threshold voltage distribution having a higher level than the first threshold voltage distribution, the method comprising:
defining a first program start voltage and a second program start voltage higher than the first program start voltage;
programming first memory cells among the MLC to the first program state using a program operation that begins programming of the first memory cells at the first program start voltage; and
programming second memory cells among the MLC to the second program state using a program operation that begins programming of the second memory cells at the second program start voltage.

2. The method of claim 1, wherein the second threshold voltage distribution has a minimum threshold voltage and the second program start voltage is selected in accordance with the minimum threshold voltage.

3. The method of claim 1, further comprising:
inhibiting the programming of the first memory cells once the programming of the first memory cells is complete.

4. The method of claim 3, further comprising:
inhibiting the programming of the second memory cells during at least a first portion of a time period during which the first memory cells are programmed.

5. The method of claim 4, further comprising:
ending the inhibiting of the programming of the second memory cells once programming of the first memory cells is complete.

6. The method of claim 4, further comprising:
ending the inhibiting of the programming of the second memory cells during a second portion of the time period during which the first memory cells are programmed, wherein the second portion of the time period follows the first portion of the time period.

7. The method of claim 4, wherein the inhibiting of the programming of the second memory cells comprises applying a logically high control signal to respective bit lines connected to the second memory cells during an inhibit interval.

8. A method of programming a memory system including multi-level memory cells (MLC) configured to be programmed in accordance with first through Nth program states, wherein each one of the first through Nth program states is respectively indicated by a successively higher threshold voltage distribution, the method comprising:
defining first through Nth program start voltages respectively corresponding to the first through Nth program states;
programming an Mth set of MLC to an Mth program state among the first through Nth program states by initially applying an Mth program start voltage, ‘N’ being a natural number greater than 2, and ‘M’ being a natural number less than or equal to N,
wherein the Mth program start voltage is higher than a first program start voltage initially applied during the programming a first set of MLC to the first program state, and the Mth program start voltage is lower than or equal to an Nth program start voltage initially applied during the programming of an Nth set of MLC to the Nth program state.

9. The method of claim 8, wherein each one of the first through Nth program start voltages is different, the first program start voltage being the lowest, the Nth program start voltage being the highest, and each one of the second through N−1 th program start voltages being successively higher across a range extending from the first program start voltage to the Nth program start voltage.

10. The method of claim 9, further comprising:
inhibiting the programming of the first set of MLC once programming of the first set of MLC is complete.

11. The method of claim 9, further comprising:
inhibiting the programming of the Mth set of MLC during at least a first portion of a time period during which the first set of MLC are programmed.

12. The method of claim 11, further comprising:
ending the inhibiting of the programming of the Mth set of MLC once programming of the first set of MLC is complete.

13. The method of claim 11, further comprising:
ending the inhibiting of the programming of the Mth set of MLC during at least a portion of a time period during which an Lth set of MLC are programmed to an Lth program state immediately preceding the programming of the Mth set of MLC.

14. The method of claim 13, wherein the inhibiting of the programming of the Mth set of MLC comprises applying a logically high control signal to respective bit lines connected to the Mth set of MLC during an inhibit interval.

15. A method of programming a memory system including multi-level memory cells (MLC) configured to be programmed in accordance with a selected one of first through Nth program states, wherein each one of the first through Nth program states is indicated by a respective and successively higher threshold voltage distribution, the method comprising:
defining respective first through Kth program start voltages;
grouping at least the first program state into a first group of program states, and grouping at least the Nth program state into a second group of program states to define K groups of program states;
programming a first set of MLC to the first program state by initially applying a first program start voltage;
programming a Jth set of MLC to a Jth program state, and thereafter programming a Jth+1 set of MLC to a Jth+1 program state by initially applying a Jth program start voltage higher than the first program start voltage, wherein the Jth program state and the Jth+1 program state are grouped in an Dth group of program states,
wherein ‘N’, ‘K’, ‘J’ and ‘D’ are respective natural numbers, N being greater than 3, K being less than N, J being less than N and greater than 1, and D being less than K.

16. The method of claim 15, further comprising:
inhibiting the programming of the first set of MLC once the programming of the first set of MLC is complete.

17. The method of claim 16, further comprising:
inhibiting the programming of the Jth+1 set of MLC during at least a first portion of a time period during which the Jth set of MLC are programmed.

18. The method of claim 17, further comprising:
ending the inhibiting of the programming of the Jth+1 set of MLC once programming of the Jth set of MLC is complete.

19. The method of claim 18, further comprising:
ending the inhibiting of the programming of the Jth+1 set of MLC during a second portion of the time period during which the Jth set of MLC are programmed, wherein the second portion of the time period follows the first portion of the time period.

20. The method of claim 18, wherein the inhibiting of the programming of the Jth+1 set of MLC comprises applying a logically high control signal to respective bit lines connected to the Jth+1 set of MLC during an inhibit interval.
